(19) United States
(12) Patent Application Publication
(10) Pub. No.: US 2012/0175651 A1
(43) Pub. Date: Jul. 12, 2012

(54) LIGHT EMITTNG MODULE, METHOD OF MANUFACTURING THE SAME AND DISPLAY APPARATUS HAVING THE SAME

(75) Inventors: Kyung-Min KIM, Asan-si (KR); Seok-Hyun NAM, Seoul, (KR); Ju-Young YOON, Seoul, (KR)

(73) Assignee: SAMSUNG ELECTRONICS CO., LTD., Suwon-si (KR)

(21) Appl. No.: 13/168,113

(22) Filed: Jun. 24, 2011

(30) Foreign Application Priority Data
Jan. 7, 2011 (KR) 2011-0001778

(51) Int. Cl. H01L 33/60; H01L 33/62

(52) U.S. Cl. 257/91; 257/88; 438/28; 257/E33.055; 257/E33.06

(57) ABSTRACT

A light emitting module includes a light emitting package and a lead frame. The light emitting package includes a light emitting chip emitting light, a first lead electrically connected to the light emitting chip, and a second lead spaced apart from the first lead and electrically connected to the light emitting chip. The light emitting package is mounted on the lead frame. The lead frame includes a third lead electrically connected to the first lead, a fourth lead electrically connected to the second lead and a molding part including the third lead and the fourth lead therein.

This application claims priority to Korean Patent Application No. 2011-0001778, filed on Jan. 7, 2011, and all the benefits accruing therefrom under 35 U.S.C. §119, the contents of which are herein incorporated by reference in their entirety.

### BACKGROUND OF THE INVENTION

1. Field of the Invention

Exemplary embodiments of the invention relate to a light emitting module, a method of manufacturing the light emitting module and a display apparatus having the light emitting module. More particularly, embodiments of the invention relate to a light emitting module including a lead frame, a method of manufacturing the light emitting module and a display apparatus having the light emitting module.

2. Description of the Related Art

In general, a liquid crystal display (“LCD”) apparatus has various advantages such as a thinner thickness, a lower driving voltage, a lower power consumption, etc., compared to other display apparatuses such as a cathode ray tube (“CRT”) apparatus and a plasma display panel (“PDP”) apparatus. Therefore, the LCD apparatus is used in monitors, laptop computers, mobile phones, television receiver sets, etc. The LCD apparatus includes an LCD panel displaying an image using a light transmittance of liquid crystal molecules, and a backlight assembly disposed under the liquid crystal display panel to provide light to the LCD panel.

The backlight assembly includes a light source generating the light required to display the image on the LCD panel. The backlight assembly employs a cold cathode fluorescent lamp (“CCFL”), a flat fluorescent lamp (“FFL”), a light emitting diode (“LED”), etc., as the light source. The LED has a merit such as a high light-emitting efficiency, a long lifetime, a low power consumption, eco-friendly characteristics, etc., so that the LED has been employed in various fields.

When the LED is employed as the light source of the backlight assembly, the LED is manufactured as a package type in which a light emitting chip is mounted on an inner portion of a case, and is electrically connected to a printed circuit board (“PCB”) through a lead that is electrically connected to the light emitting chip. The light emitting package is manufactured as a top-view type or a side-view type in accordance with a usage thereof.

In the side-view type, the PCB is disposed under a light guide plate in the backlight assembly, and thus a thickness of the display apparatus is larger due to the PCB.

In the top-view type, the PCB faces the light guide plate disposing the light emitting package between the PCB and the light guide plate. However, a width of the PCB is larger than a width of the light emitting package, and thus the thickness of the display apparatus is larger.

In addition, the PCB is inferior to dissipate heat generated from the light emitting chip of the light emitting package, and thus a size of the light guide plate may be changed. Therefore, defects of the display apparatus may occur.

### BRIEF SUMMARY OF THE INVENTION

Exemplary embodiments of the invention provide a light emitting module which is excellent to dissipate heat and having a relatively small thickness.

Exemplary embodiments of the invention also provide a method of manufacturing the above-mentioned light emitting module.

Exemplary embodiments of the invention also provide a display apparatus having the above-mentioned light emitting module.

According to an exemplary embodiment of the invention, a light emitting module includes a light emitting package and a lead frame. The light emitting package includes a light emitting chip emitting light, a first lead electrically connected to the light emitting chip, and a second lead spaced apart from the first lead and electrically connected to the light emitting chip. The light emitting package is mounted on the lead frame. The lead frame includes a third lead electrically connected to the first lead, a fourth lead electrically connected to the second lead and a molding part including the third lead and the fourth lead therein.

In one embodiment, the third lead and the fourth lead may each include a circuit pattern having a quadrangle shape and a line shape.

In one embodiment, the light may be emitted from the light emitting package in a direction opposite to a direction in which the lead frame is disposed.

In one embodiment, the light emitting module may include a case including the light emitting chip therein, and having an open top portion through which the light emitted from the light emitting chip exits. A width of the case taken in a first direction may be substantially same as a width of the lead frame in the first direction.

In one embodiment, the molding part is a bar shape, and a plurality of the light emitting chips may be mounted on the molding part.

In one embodiment, the light emitting package may further include a fifth lead on which the light emitting chip is mounted, and the lead frame may further include a heat dissipating portion connected to the fifth lead and dissipating heat generated from the light emitting chip to outside of the light emitting module.

According to another exemplary embodiment of the invention, there is provided a method of manufacturing a light emitting module. In the method, light emitting packages are formed. Each of the light emitting packages includes a light emitting chip emitting light, a first lead electrically connected to the light emitting chip and a second lead electrically connected to the light emitting chip. A third lead electrically connected to the first lead, and a fourth lead electrically connected to the second lead, are formed. The third lead and the fourth lead are covered with a molding resin. The lead frame is formed by hardening the molding resin. The light emitting packages on the lead frame are mounted in a matrix pattern. The lead frame on which the light emitting packages are mounted is cut in a longitudinal direction of the light emitting packages.

In one embodiment, the light emitting packages may be mounted on the lead frame in the matrix pattern using a surface mount technology (“SMT”).

In one embodiment, the forming the third lead and the fourth lead may include forming a circuit pattern on the third and fourth leads using a punching method or a photo mask method.

According to still another exemplary embodiment of the invention, a display apparatus includes a light guide plate, a light emitting module and a display panel. The light guide plate includes a light incident surface into which light is incident, and a light exiting surface connected to the light incident surface and through which the light exits. The light emitting module includes a light emitting package, and a lead frame on which the light emitting package is mounted. The light emitting package includes a light emitting chip emitting the light to the incident surface, a first lead electrically connected to the light emitting chip, and a second lead spaced apart from the first lead and electrically connected to the light emitting chip. The lead frame includes a third lead electrically connected to the first lead, a fourth lead electrically connected to the second lead and a molding part including the third lead and the fourth lead therein. The display panel displays an image using the light exiting from the light exiting surface of the light guide plate.

In one embodiment, the display apparatus may further include a receiving container including a bottom plate, and a sidewall extending from the bottom plate. The light guide plate and the light emitting module are in the receiving container. The sidewall of the receiving container may face the incident surface of the light guide plate, and the lead frame may contact the sidewall.

In one embodiment, the light emitting package may further include a fifth lead on which the light emitting chip is mounted, and the lead frame may further include a heat dissipating portion connected to the fifth lead. The heat dissipating portion dissipates heat generated from the light emitting chip to outside of the light emitting module.

In one embodiment, the heat dissipating portion of the lead frame may be in contact with the sidewall of the receiving container.

In one embodiment, the display apparatus may further include a reflection sheet between the receiving container and the light emitting module, and between the receiving container and the light guide plate, to reflect the light.

In one embodiment, the light guide plate may further include a side surface extending from the light exiting surface, and a combining groove extending from both the light exiting surface and the side surface.

In one embodiment, the molding part of the lead frame may include a main portion, an extending portion and a protruding portion. The main portion may face the light emitting chip, and include the third lead and the fourth lead therein. The extending portion may extend from the main portion toward the light guide plate. The protruding portion may be protruded from the extending portion and may be combined with the combining groove of the light guide plate.

In one embodiment, the combining groove may be adjacent to the incident surface.

In one embodiment, the display apparatus may further include optical sheets between the light exiting surface of the light guide plate and the display panel, to increase efficiency of the light exiting from the light guide plate. The combining groove may extend from the light exiting surface except for an area overlapping the optical sheets.

In one embodiment, the light guide plate may further include a light reflecting surface opposing the light exiting surface, and side surfaces connecting the light exiting surface with the light reflecting surface. The light incident surface of the light guide plate may be a chamfered surface through which adjacent side surfaces adjacent are connected to each other.

In one embodiment, the molding part of the lead frame may have a triangular column planar shape having a right angle, and the right angle of the triangular column is disposed at a corner portion of the receiving container.

According to the exemplary embodiments of the invention, a lead frame dissipating heat more efficiently is between a light emitting package and a receiving container, and thus the heat generated from a light emitting chip of the light emitting package may be quickly dissipated to outside of the light emitting module. In addition, the light emitting package is mounted on the lead frame having a width in a thickness direction of the display apparatus which is substantially same as a width of the light emitting package, and supplying a driving voltage to the light emitting chip, and thus an overall thickness of the display apparatus may be decreased.

### BRIEF DESCRIPTION OF THE DRAWINGS

The above and other features of the invention will become more apparent by describing in detailed exemplary embodiments thereof with reference to the accompanying drawings, in which:

FIG. 1 is an exploded perspective view illustrating an exemplary embodiment of a display apparatus according to the invention;

FIG. 2 is a cross-sectional view taken along line I-I′ of FIG. 1;

FIG. 3 is a perspective view illustrating an exemplary embodiment of a portion of the light emitting module of FIG. 1;

FIG. 4 is a cross-sectional view taken along line II-II′ of FIG. 3;

FIGS. 5A to 5G are perspective views explaining an exemplary embodiment of a method of manufacturing the light emitting module of FIG. 1;

FIG. 6 is a cross-sectional view illustrating another exemplary embodiment of a light emitting module according to the invention;

FIG. 7 is an exploded perspective view illustrating another exemplary embodiment of a display apparatus according to the invention;

FIG. 8 is a cross-sectional view taken along line III-III′ of FIG. 7;

FIG. 9 is an exploded perspective view illustrating still another exemplary embodiment of a display apparatus according to the invention;

FIG. 10 is a cross-sectional view of a light emitting module in FIG. 9; and

FIG. 11 is an enlarged plan view of portion ‘A’ in FIG. 9.

### DETAILED DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, “connected” includes physically and/or electrically connected. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” relative to other elements or features would then be oriented “upper” or “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be explained in detail with reference to the accompanying drawings.

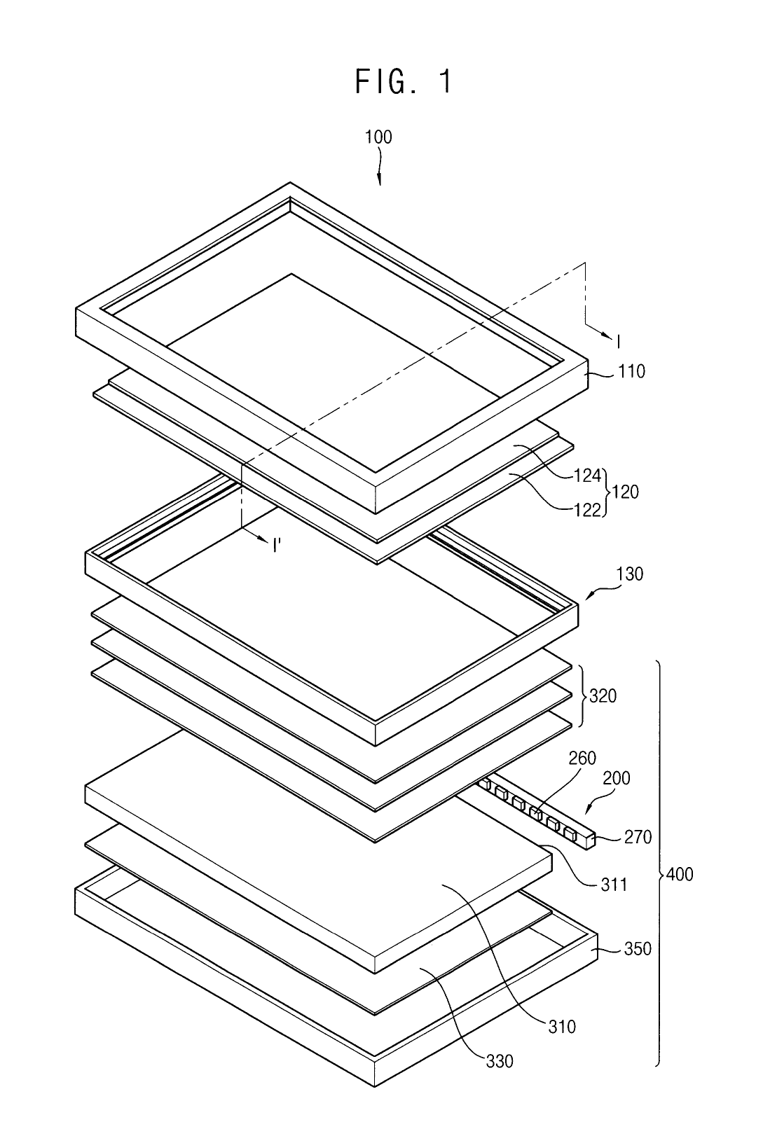

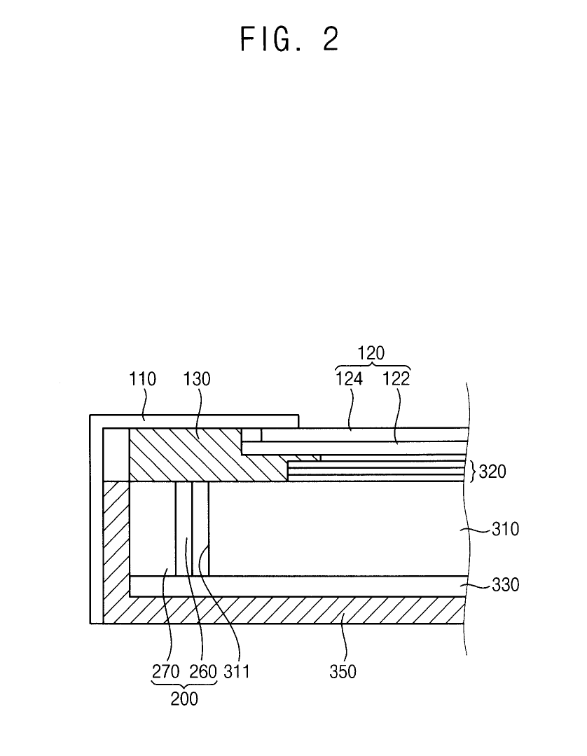

FIG. 1 is an exploded perspective view illustrating an exemplary embodiment of a display apparatus according to the invention. FIG. 2 is a cross-sectional view taken along line I-I′ of FIG. 1.

Referring to FIGS. 1 and 2, the display apparatus 100 of the illustrated exemplary embodiment includes a top chassis 110, a display panel 120 and a backlight assembly 400.

The top chassis 110 is disposed over the display panel 120 to protect the display panel 120 from an external impact, and a window is extended through a thickness of the top chassis 110 to expose a display area of the display panel 120.

The display panel 120 includes a first substrate 122, a second substrate 124 facing the first substrate 122, and a liquid crystal layer (not shown) disposed between the first and second substrates 122 and 124. The display panel 120 displays an image using light exiting from a light exiting surface of a light guide plate 310 of the backlight assembly 400.

The backlight assembly 400 is disposed under and overlapping the display panel 120 to provide the display panel 120 with the light.

The backlight assembly 400 may include a light emitting module 200, the light guide plate 310, optical sheets 320, a reflection sheet 330 and a receiving container 350.

The light emitting module 200 includes a plurality of light emitting packages 260 generating and emitting the light, and a lead frame 270 on which the light emitting packages 260 are mounted. A signal wiring (not shown) for providing the light emitting packages 260 with a driving voltage is on the lead frame 270.

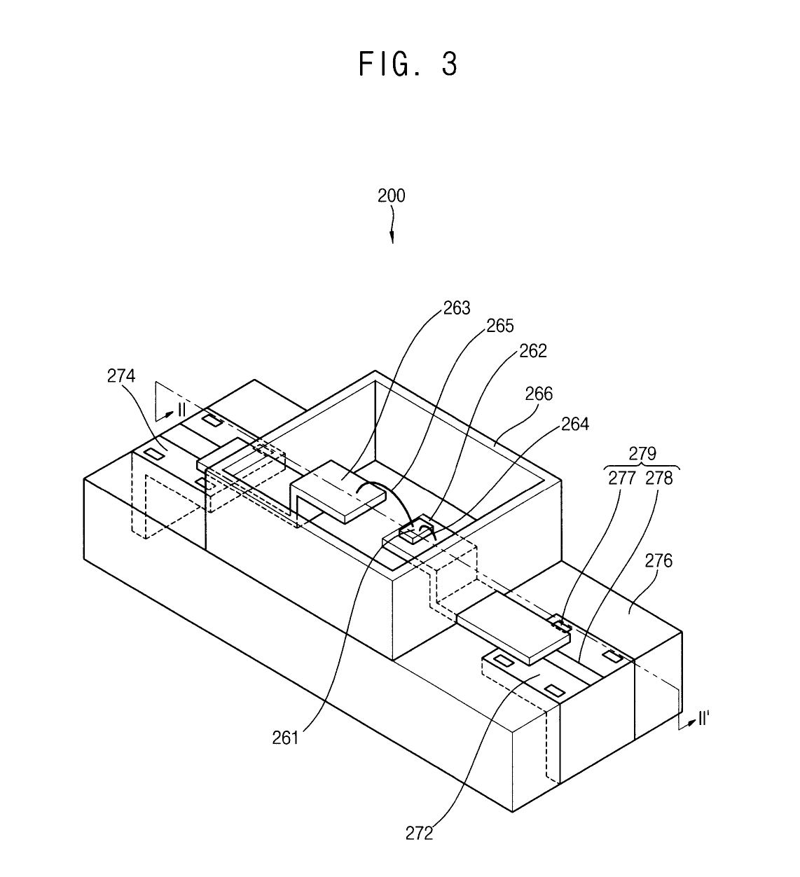

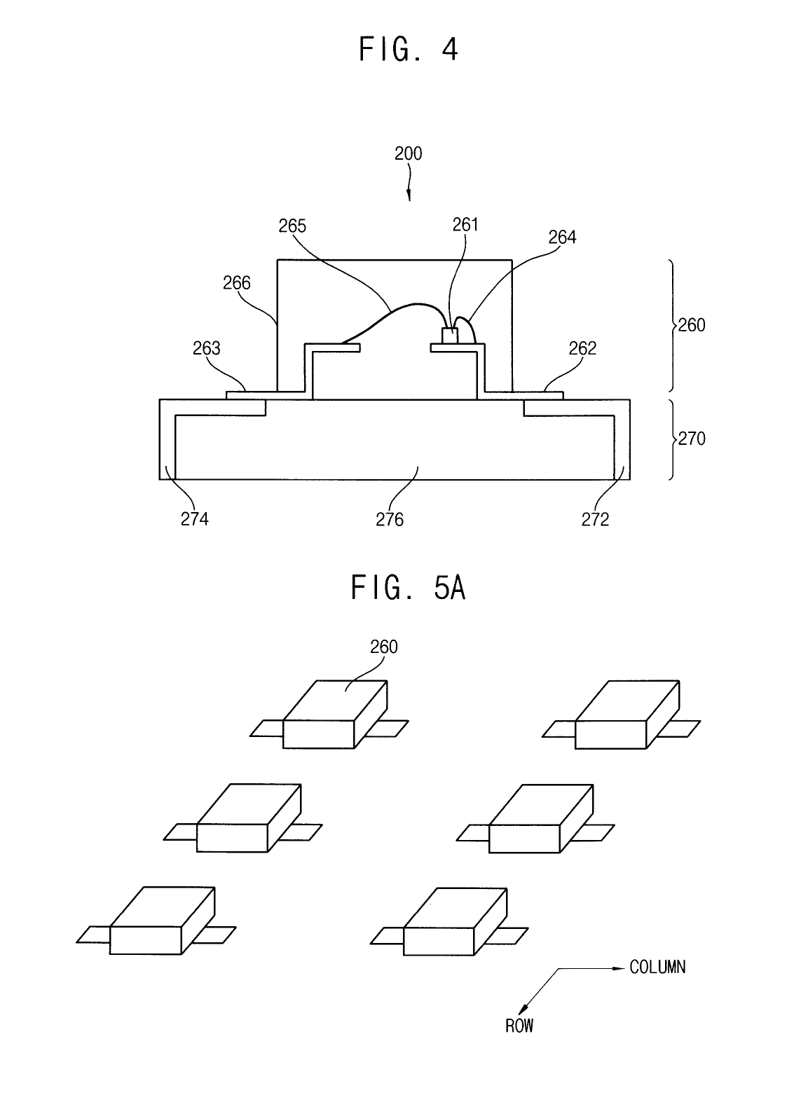

The light emitting module 200 may be on at least one side surface of the light guide plate 310. In one exemplary embodiment, for example, the light emitting module 200 may be at a first side surface of the light guide plate 310 along a direction substantially parallel with a relatively longer side of the display panel 120, as illustrated in FIG. 1. Alternatively, the light emitting module 200 may be at each of two opposing sides of the light guide plate 310 along a direction substantially parallel with a relatively shorter side of the display panel 120. A structure of the LED packages 260 will be explained with reference to FIGS. 3 and 4.

The light guide plate 310 is disposed at a first side of the light emitting module 200 to receive the light emitted from the light emitting module 200 through a light incident surface 311 and to guide the light toward the display panel 120.

The optical sheets 320 are disposed over the light guide plate 310 to enhance an efficiency of the light emitted from the light guide plate 310. The optical sheets 320 may include a diffusion sheet, a prism sheet and/or a light-condensing sheet.

The reflection sheet 330 is disposed between the light guide plate 310 and the receiving container 350, and between the light emitting module 200 and the receiving container 350, to reflect light leaked from the light emitting module 200 and from the light guide plate 310.

The receiving container 350 includes a bottom plate, and sidewalls extending from edges of the bottom plate, to form a receiving space. In one exemplary embodiment, for example, the receiving container 350 may include a metal material such as aluminum (Al). The receiving container 350 receives the reflection sheet 330, the light guide plate 310, the light emitting module 200 and the optical sheets 320 therein. The light emitting module 200 may be disposed to make contact with the sidewall of the receiving container 350 which faces the incident surface 311 of the light guide plate 310. A thickness direction of the display apparatus 100 is taken in a first direction, for example, perpendicular to the bottom plate of the receiving container 350.

The display apparatus 100 may further include a mold frame 130. A portion of the mold frame 130 is disposed between the display panel 120 and the optical sheets 320 to support the display panel 120. In addition, the mold frame 130 fixes the light guide plate 310, the optical sheets 320 and the reflection sheet 330 to the receiving container 350.

FIG. 3 is a perspective view illustrating a portion of the light emitting module 200 of FIG. 1. FIG. 4 is a cross-sectional view taken along line II-II′ of FIG. 3.

Referring to FIGS. 1 to 4, the light emitting module 200 includes the light emitting package 260, and the lead frame 270 on which the light emitting package 260 is mounted.

The light emitting package 260 includes a light emitting chip 261, a first lead 262, a second lead 263, a first wire 264, a second wire 265 and a case 266.

The light emitting chip 261 emits light, and for example, the light emitting chip 261 may include a light emitting diode (“LED”) chip generating the light using an electroluminescent effect.

The light emitting chip 261 is mounted on the first lead 262 within the case 266. The first lead 262 is electrically connected to a first electrode of the light emitting chip 261 through the first wire 264 to transmit a first power voltage to the light emitting chip 261. A first portion of the first lead 262 penetrates the case 266 to be within the case 266, while a second portion is extended outside of the case 266.

The second lead 263 is spaced apart from the first lead 262. The second lead 263 is electrically connected to a second electrode of the light emitting chip 261 through the second wire 265 to transmit a second power voltage having a polarity different from the polarity of the first power voltage to the light emitting chip 261. A first portion of the second lead 263 penetrates the case 266 to be within the case 266, while a second portion is extended outside of the case 266. In the illustrated exemplary embodiment, the light emitting chip 261 is mounted on the first lead 262. Alternatively, the light emitting chip 261 may be mounted on the second lead 263.

The first wire 264 electrically connects the first electrode of the light emitting chip 261 to the first lead 262, and the second wire 264 electrically connects the second electrode of the light emitting chip 261 to the second lead 263.

The case 266 includes an upper portion, a bottom plate and four sidewalls to form a receiving space. The case 266 may include an insulating material protecting and insulating the light emitting chip 261, and the first and second leads 262 and 263. In one exemplary embodiment, for example, the case 266 may include a polymer or a ceramic. In addition, a reflection layer (not shown) may be further on an inner surface of the case 266 to reflect the light generated from the light emitting chip 261.

An opening portion through which the light emitting from the light emitting chip 261 extends through the upper portion of the case 266. The opening portion of the case 266 faces the incident surface 311 of the light guide plate 310, and the bottom plate of the case 266 makes contact with a surface of the lead frame 270.

The lead frame 270 includes a third lead 272, a fourth lead 274 and a molding part 276, and the lead frame 270 is disposed on the sidewall of the receiving container 350 which faces the incident surface 311 of the light guide plate 310.

The third lead 272 receives the first power voltage from an external power supplying part, and a first terminal of the third lead 272 is electrically connected to the first lead 262 of which a portion penetrates the case 266 to transmit the first power voltage to the first lead 262.

In addition, a second terminal of the third lead 272 is perpendicularly bent from the first terminal of the third lead 272 to make contact with the sidewall of the receiving container 350. In one exemplary embodiment, for example, the third lead 272 may have an ‘L’ shape, and may include a copper material. However, the material of the third lead 272 is not limited thereto, and the third lead 272 may include a material having electrical conductivity and heat conductivity.

The fourth lead 274 receives the second power voltage from the external power supplying part, and a first terminal of the fourth lead 274 is electrically connected to the second lead 263 of which a portion penetrates the case 266 to transmit the second power voltage to the second lead 263.

In addition, a second terminal of the fourth lead 274 is perpendicularly bent from the first terminal of the fourth lead 274 to make contact with the sidewall of the receiving container 350. In one exemplary embodiment, for example, the fourth lead 274 may have an ‘L’ shape, and may include a copper material. However, the material of the fourth lead 274 is not limited thereto, and the fourth lead 274 may include a material having electrical conductivity and heat conductivity.

Thus, since the third lead 272 and the fourth lead 274 make contact with the sidewall of the receiving container 350, the third lead 272 and the fourth lead 274 may dissipate heat generated from the light emitting chip 261 to the receiving container 350.

In addition, each of the third lead 272 and the fourth lead 274 may include a circuit pattern 279 having a pad 277 of a quadrangle planar shape and an electrical circuit 278 of a line shape in the plan view. In an exemplary embodiment, the circuit pattern 279 may be formed using a punching method or a photo mask method. Thus, the lead frame 270 may replace a conventional printed circuit board (“PCB”).

The molding part 276 faces the bottom plate of the case 266. The third lead 272 and the fourth lead 274 are inside of the molding part 276. Outer surfaces of the third lead 272 and the fourth lead 274 are coplanar with upper and side surfaces of the molding part 276, as illustrated in FIGS. 3 and 4. Inner surfaces of the third lead 272 and the fourth lead 274 are within outer edges of the molding part 276. The second terminal of the third and fourth leads 272 and 274 is exposed to an outside of the lead frame 270 and contacts the sidewall of the receiving container 350. In one exemplary embodiment, for example, the molding part 276 may include an epoxy material in which the third lead 272 and the fourth lead 274 may be molded.

A width of the molding part 276 in the first direction (e.g., the thickness direction of the display apparatus 100) may be substantially the same as a width of the case 266, and thus a width of the lead frame 270 may be substantially the same as a width of the case 266. Therefore, the light emitting module 200 may decrease a thickness of the display apparatus 100, and a light emitting chip bigger than a conventional light emitting chip may be used.

In addition, the molding part 276 may have a bar shape, such that the molding part 276 is an oblong, rectilinear, uniform thickness solid member, and a plurality of light emitting packages 260 are mounted on one of the molding part 276, however, the invention is not limited thereto. Thus, the molding part 276 may have variable shapes such as a rectangular shape, a triangular column shape and a pyramid shape.

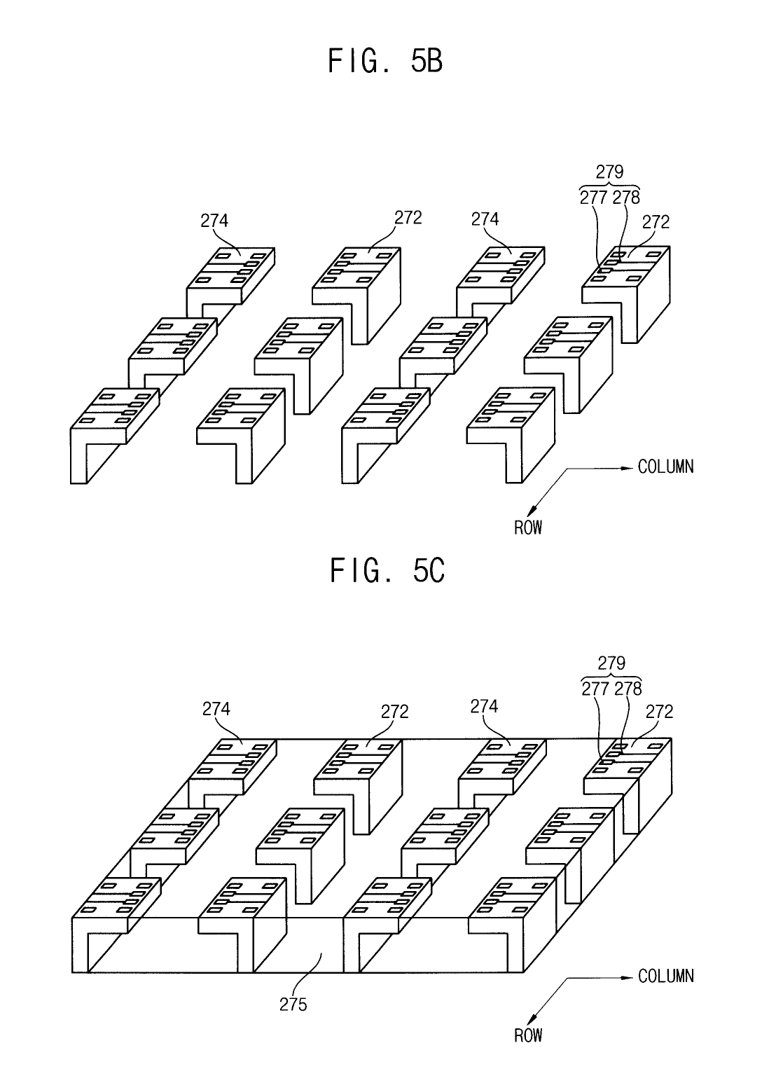

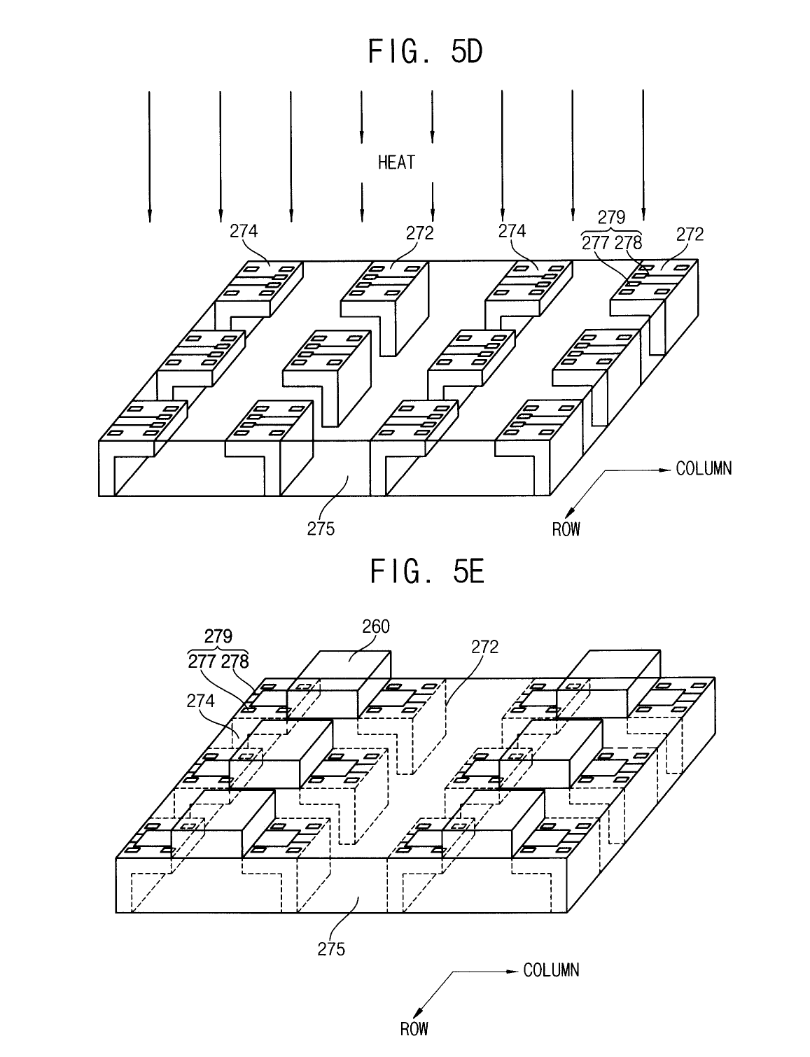

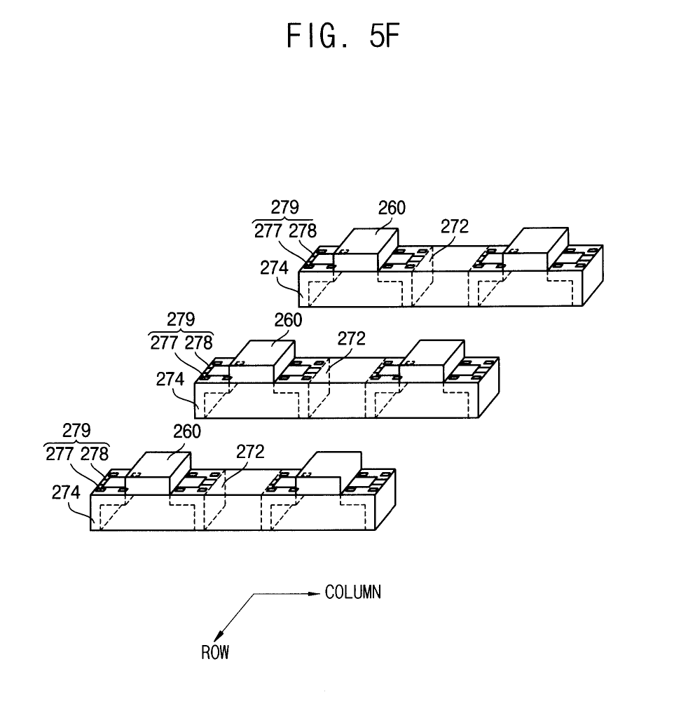

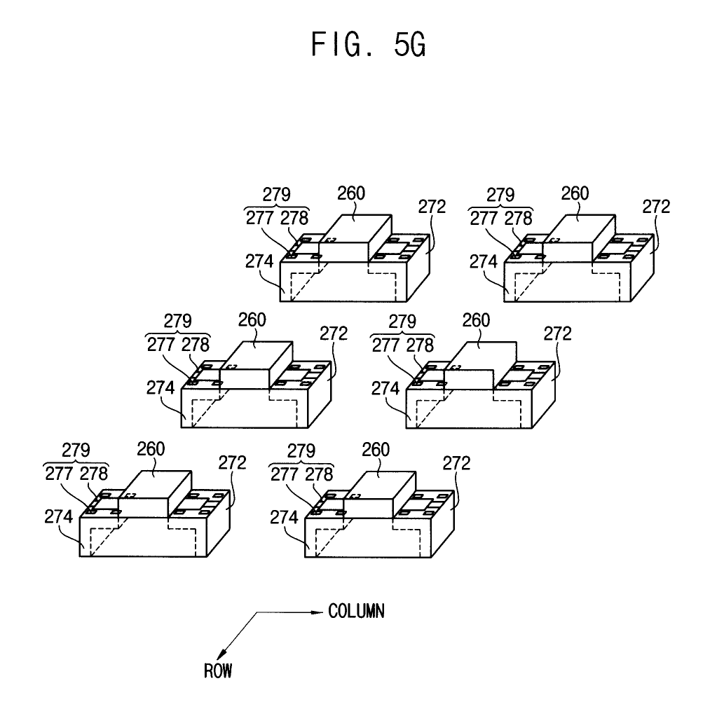

FIGS. 5A to 5G are perspective views explaining a method of manufacturing the light emitting module of FIG. 1.

Referring to FIG. 1 and FIG. 5A, the light emitting package 260 is formed. In one exemplary embodiment, for example, the first lead 262 (shown in FIGS. 3 and 4) on which the light emitting chip 261 (shown in FIGS. 3 and 4) is mounted and which is electrically connected to the first electrode of the light emitting chip 261, is formed. The second lead 263 (shown in FIGS. 3 and 4) electrically connected to the second electrode of the light emitting chip 261 is formed. The first wire 264 (shown in FIGS. 3 and 4) electrically connecting the light emitting chip 261 to the first lead 262, and the second wire 265 (shown in FIGS. 3 and 4) electrically connecting the light emitting chip 261 to the second lead 263, are formed. The case 266 (shown in FIGS. 3 and 4) which receives the light emitting chip 261 and includes the opening through which the light generated from the light emitting chip 261 exits, and through which the first lead 262 and the second lead 263 penetrate, is formed. Accordingly, the light emitting package 260 is formed.

Referring to FIG. 5B, the third lead 272 and the fourth lead 274 of the lead frame 270 are formed. In one exemplary embodiment, for example, each of the third lead 272 and the fourth lead 274 may have the ‘L’ shape, and each of the third lead 272 and the fourth lead 274 may include a copper material. However, the material of the third and fourth leads 272 and 274 is not limited thereto. Thus, each of the third lead 272 and the fourth lead 274 may include a material having electrical conductivity and heat conductivity. Each of the third lead 272 and the fourth lead 274 may include the circuit pattern 279 having the pad 277 of the quadrangle planar shape and the electrical circuit 287 of the line shape, and the circuit pattern 279 may be formed using the punching method or the photo mask method.

Referring to FIG. 5C, a molding resin 275 covering the third lead 272 and the fourth lead 274 is injected. In one exemplary embodiment, for example, the molding resin 275 covers the third lead 272 except for an upper surface of the third lead 272 making contact with the first lead 262 of the light emitting package 260, and the molding resin 275 covers the fourth lead 274 except for an upper surface of the fourth lead 274 making contact with the second lead 263 of the light emitting package 260. In an exemplary embodiment, or example, the molding resin 275 may include an epoxy material.

Referring to FIG. 5D, heat is supplied to the molding resin 275 to harden the molding resin 275, and thus the lead frame 270 is formed. The molding part 276 of the lead frame 270 is a single, unitary, indivisible member.

Referring to FIG. 5E, the light emitting packages 260 are mounted on the lead frame 270 in a matrix pattern of columns and rows, and are spaced apart from each other. In one exemplary embodiment, for example, the light emitting packages 260 are arranged so that the first lead 262 makes contact with the third lead 272, and the second lead 263 makes contact with the fourth lead 274. The light emitting packages 260 are mounted on the lead frame 270 using a surface mount technology (“SMT”).

Referring to FIG. 5F, the lead frame 270 is cut in a column direction which may be parallel to a longitudinal direction of the light emitting packages 260. In one exemplary embodiment, for example, the lead frame 270 is cut at a location between the light emitting packages 260 disposed spaced apart from each other, and thus a preliminary light emitting module 200 to finally have a bar shape on which the light emitting packages are mounted, is formed.

Referring to FIG. 5G, the lead frame 270 is further cut in a row direction at a location between the light emitting packages 260 disposed spaced apart from each other, and a final individual light emitting module 200 may be formed including the light emitting package 260 unit. The row direction may be parallel to a transverse direction of the light emitting packages 260.

According to the illustrated exemplary embodiment, the light emitting package 260 is mounted on the lead frame 270 having the width substantially same as the width of the light emitting package 260 and supplying a driving voltage to the light emitting chip 261, and thus the thickness of the display apparatus 100 may be decreased.

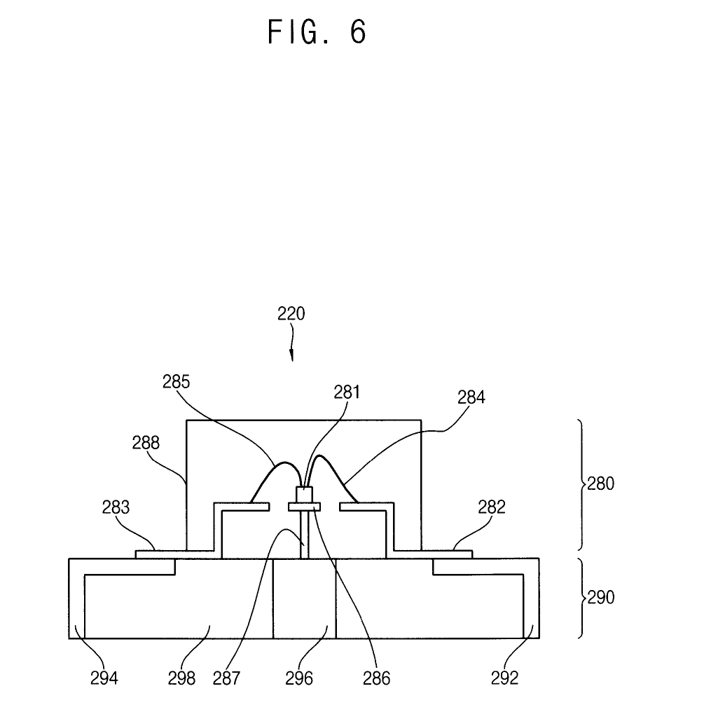

FIG. 6 is a cross-sectional view illustrating another exemplary embodiment of a light emitting module according to the invention.

A light emitting module 220 according to the illustrated exemplary embodiment may be included in a display apparatus, and the display apparatus including the light emitting module 220 is substantially the same as the display apparatus 100 according to the previous exemplary embodiment in FIG. 1 except for the light emitting module 220. Thus, the same reference numerals will be used to refer to same or like parts as those described in the previous exemplary embodiment and any further repetitive explanation concerning the above elements will be omitted.

Referring to FIG. 6, the light emitting module 220 includes a light emitting package 280 and a lead frame 290.

The light emitting package 280 includes a light emitting chip 281, a first lead 282, a second lead 283, a first wire 284, a second wire 285, a fifth lead 286, a connection part 287 and a case 288.

The light emitting chip 281 is disposed in the case 288 and generates light.

The first lead 282 is electrically connected to a first electrode of the light emitting chip 281 through the first wire 284 in the case 288, and a portion of the first lead 282 penetrates the case 288. The second lead 283 is electrically connected to a second electrode of the light emitting chip 281 through the second wire 285 in the case 288, and a portion of the second lead 283 penetrates the case 288.

The light emitting chip 281 is mounted on the fifth lead 286, and the connection part 287 contacting the fifth lead 286 transmits heat generated from the light emitting chip 281.

The lead frame 290 includes a third lead 292, a fourth lead 294, a heat dissipating portion 296 and a molding part 298.

The third lead 292 receives a first power voltage from an external power supplying part, and a first terminal of the third lead 292 is electrically connected to the first lead 282 which penetrates the case 288 to transmit the first power voltage to the first lead 282. The fourth lead 294 receives a second power voltage from the external power supplying part, and a first terminal of the fourth lead 294 is electrically connected to the second lead 283 which penetrates the case 288 to transmit the second power voltage to the second lead 283.

The heat dissipating part 296 is in the molding part 298. Outer surfaces of the heat dissipating part 296 are coplanar with upper and lower surfaces of the molding part 298. That is, the heat dissipating part 296 is in an internal area of the molding part 298. The heat dissipating portion 296 is between the connection part 287 of the light emitting package 280 and the receiving container 350 to receive the heat generated from the light emitting chip 281 and to transmit the heat to the receiving container 350. Thus, the heat generated from the light emitting chip 281 may be quickly dissipated to outside of the display apparatus.

An exemplary embodiment of a method of manufacturing the light emitting module 220 of FIG. 6 is described as follows.

The light emitting package 280 is formed. In one exemplary embodiment, for example, the first lead 282 and the second lead 283 are formed, and the fifth lead 286 and the connection part 287 connected to the fifth lead 286 are formed. The light emitting chip 281 is mounted directly on the fifth lead 286. The light emitting chip 281 and the first lead 282 are electrically connected to each other by the first wire 284, and the light emitting chip 281 and the second lead 283 are electrically connected to each other by the second wire 285. The case 288 which receives the light emitting chip 281 and through which the portion of the first lead 282 and the portion of the second lead 283 penetrate is formed, and thus the light emitting package 280 is formed.

The lead frame 290 is formed. In one exemplary embodiment, for example, the third lead 292 and the fourth lead 294 facing each other are formed, and the heat dissipating portion 296 is formed between the third lead 292 and the fourth lead 294. The third lead 292, the fourth lead 294 and the heat dissipating portion 296 are completely molded in the molding part 298, and thus the lead frame 290 is formed.

The light emitting package 280 is mounted on the lead frame 290. In one exemplary embodiment, for example, the light emitting package 280 is mounted on the lead frame 290 so that the connection part 287 connected to the fifth lead 286 of the light emitting package 280 makes contact with the heat dissipating portion 296.

According to the illustrated exemplary embodiment, the heat dissipating portion 296 connected to the fifth lead 286 on which the light emitting chip 281 is mounted and making contact with the receiving container 350 is in the lead frame 290, and thus the heat generated from the light emitting chip 281 may be promptly dissipated to outside of the display apparatus.

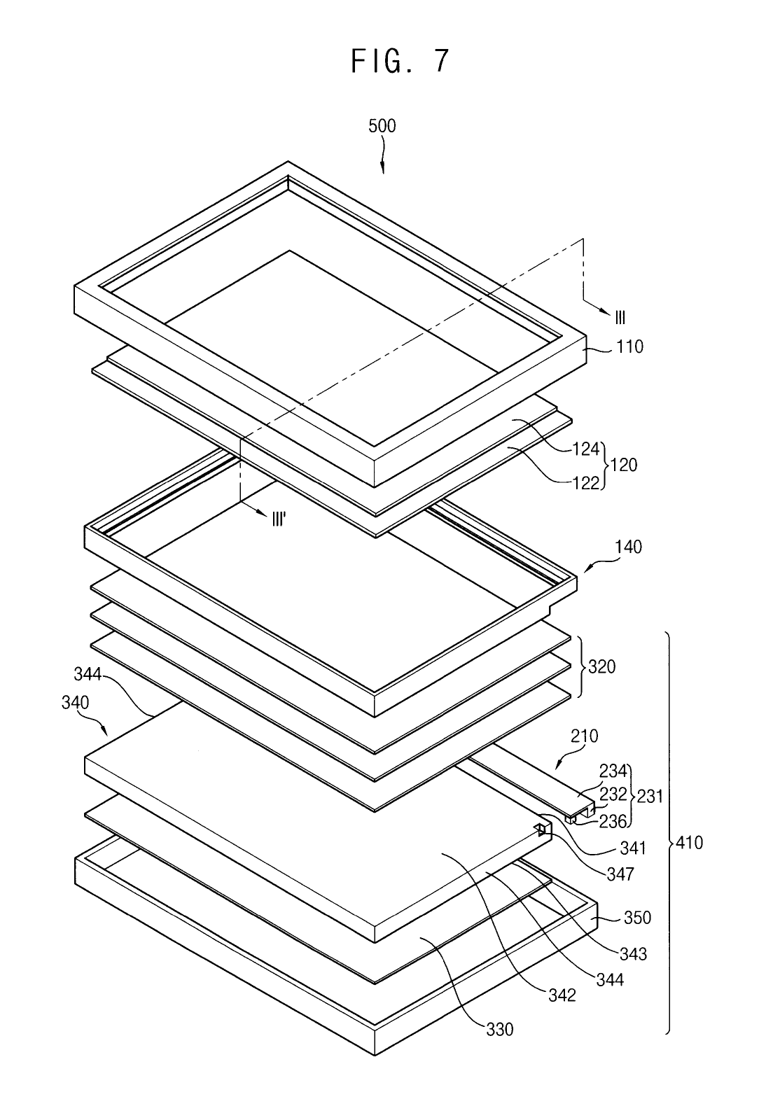

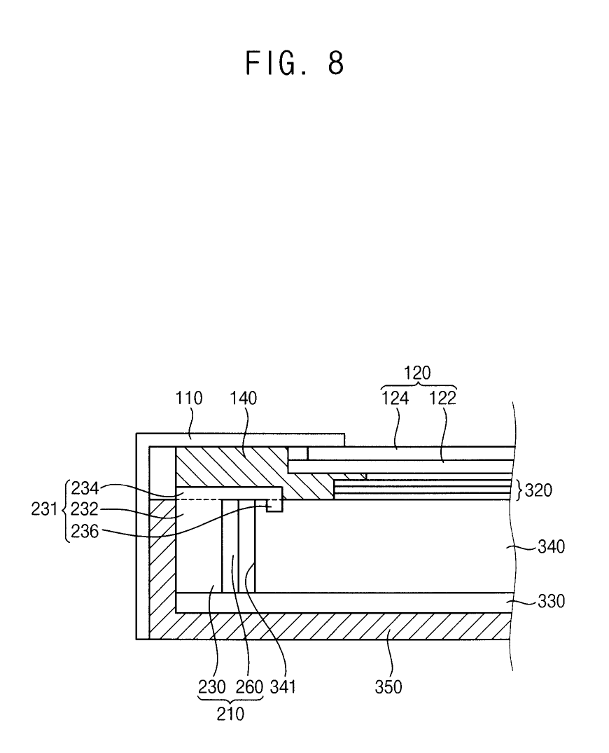

FIG. 7 is an exploded perspective view illustrating another exemplary embodiment of a display apparatus according to the invention. FIG. 8 is a cross-sectional view taken along line III-III′ of FIG. 7.

The display apparatus 500 according to the illustrated exemplary embodiment is substantially the same as the display apparatus 100 according to the previous exemplary embodiment of FIG. 1 except for a light emitting module 210 and a light guide plate 340 in a backlight assembly 410, and a mold frame 140. Thus, the same reference numerals will be used to refer to same or like parts as those described in the previous exemplary embodiment and any further repetitive explanation concerning the above elements will be omitted.

Referring to FIGS. 7 and 8, the display apparatus 500 of the illustrated exemplary embodiment includes the top chassis 110, the display panel 120, the mold frame 140 and the backlight assembly 410.

The backlight assembly 410 may include the light emitting module 210, the light guide plate 340, the optical sheets 320, the reflection sheet 330 and the receiving container 350.

The light emitting module 210 includes the light emitting packages 260 generating light, and a lead frame 230 on which the light emitting packages 260 are mounted.

The light guide plate 340 includes an incident surface 341 into which the light generated from the light emitting chip 261 is incident, a light exiting surface 342 connected to the light incident surface 341 and guiding the light supplied through the light incident surface 341 to exit the light to the display panel 120, a light reflecting surface 343 facing the light exiting surface 342, and side surfaces 344 connecting the light exiting surface 342 with the light reflecting surface 343.

The light guide plate 340 may have a combining groove 347 extended to an inner area of the light guide plate 340, from the light exiting surface 342 and the side surfaces 344. The combining groove 347 is a continuous area which extends from both the light exiting surface 342 and a side surface 344, and is open to an outside of the light guide plate 240.

Inner structures of the light emitting package 260 and the lead frame 230 are substantially the same as the light emitting package 260 and the lead frame 270 of FIGS. 1 to 4. Thus, the same reference numerals will be used to refer to same or like parts as those described in previously exemplary embodiment.

The lead frame 230 includes the third lead 272 electrically connected to the first lead 262 of the light emitting package 260, the fourth lead 274 electrically connected to the second lead 263 of the light emitting package 260, and a molding part 231 including the third lead 272 and the fourth lead 274 therein.

The molding part 231 includes a main portion 232, an extending portion 234 and a protruding portion 236. The main portion 232 faces the light emitting chip 261, and disposes the light emitting chip 261 between the light guide plate 340 and the main portion 232. The main portion 232 includes the third lead 272 and the fourth lead 274 therein. The extending portion 234 extends from the main portion 232 to the light guide plate 340. The protruding portion 236 is protruded from the extending portion 234 and is combined to the combining groove 347.

While the combining groove 347 is viewable at one side of the light guide plate 340 in FIG. 7, the combining groove 347 may be at both of opposing sides of the light exiting surface 342 adjacent to the light incident surface 341, except for (e.g., not overlapping) an area in which the optical sheets 320 are disposed. The protruding portion 236 may be extended from both of opposing end corner portions of the extending portion 234 in the direction towards the light guide plate 340.

The mold frame 140 may have a stepped portion in which the extending portion 234 of the lead frame 230 is accommodated.

An exemplary embodiment of a method of manufacturing the light emitting module 210 of FIGS. 7 and 8 is described as follows.

The light emitting package 260 is formed. In one exemplary embodiment, for example, the first lead 262 on which the light emitting chip 261 is mounted and which is electrically connected to the first electrode of the light emitting chip 261, is formed. The second lead 263 electrically connected to the second electrode of the light emitting chip 261 is formed. The first wire 264 electrically connecting the light emitting chip 261 with the first lead 262, and the second wire 265 electrically connecting the light emitting chip 261 with the second lead 263 are formed. The case 266 which receives the light emitting chip 261 and includes the opening through which the light generated from the light emitting chip 261 exits, and through which the first lead 262 and the second lead 263 penetrate, is formed, and thus the light emitting package 260 is formed.

The lead frame 230 is formed. In one exemplary embodiment, for example, the third lead 272 and the fourth lead 274 are formed. The molding part 231 includes the main portion 232 including the third lead 272 and the fourth lead 274 therein, the extending portion 234 extending from the main portion 232 to the light guide plate 340, and the protruding portion 236 protruded from the extending portion 234 is formed, and thus the lead frame 230 is formed.

The light emitting package 260 is mounted on the lead frame 230 so that the first lead 262 of the light emitting package 260 makes contact with the third lead 272 of the lead frame 230, and the second lead 263 of the light emitting package 260 makes contact with the fourth lead 274 of the lead frame 230.

According to the illustrated exemplary embodiment, the light guide plate 340 includes the combining groove 347, and the lead frame 230 includes the protruding portion 236 combined to the combining groove 347. Thus, a distance between the light emitting package 260 and the light guide plate 340 is constantly maintained, even though a size of the light guide plate 340 is changed due to the heat of the light emitting chip 281.

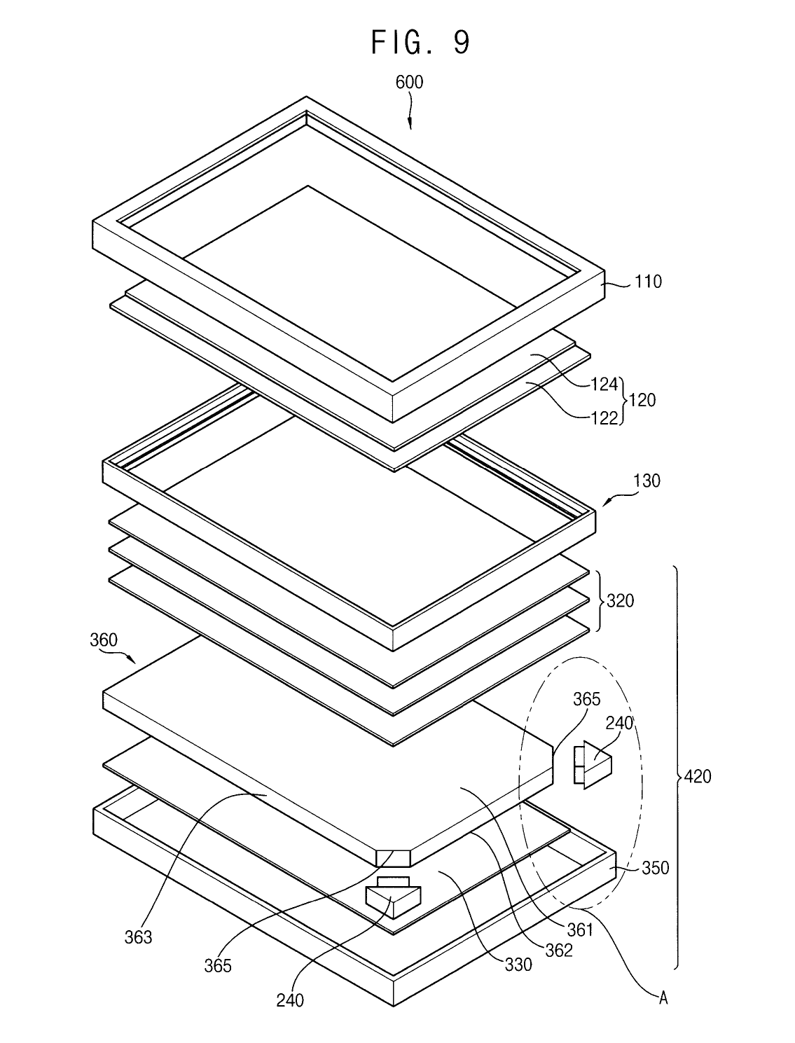

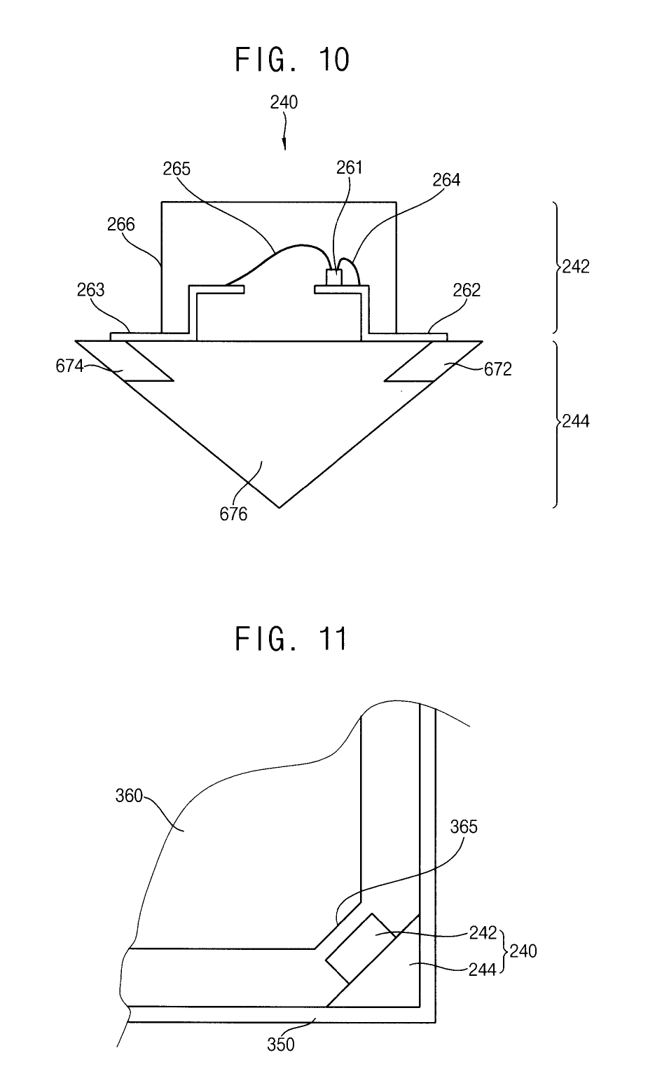

FIG. 9 is an exploded perspective view illustrating still another exemplary embodiment of a display apparatus according to the invention. FIG. 10 is a cross-sectional view of a light emitting module in FIG. 9. FIG. 11 is an enlarged plan view of a portion ‘A’ in FIG. 9.

The display apparatus 600 according to the illustrated exemplary embodiment is substantially the same as the display apparatus 100 according to the previous exemplary embodiment of FIG. 1 except for a light emitting module 240 and a light guide plate 360 in a backlight assembly 420. Thus, the same reference numerals will be used to refer to same or like parts as those described in the previous exemplary embodiment and any further repetitive explanation concerning the above elements will be omitted.

Referring to FIGS. 9 to 11, the display apparatus 600 of the illustrated exemplary embodiment includes the top chassis 110, the display panel 120, the mold frame 130 and the backlight assembly 420.

The backlight assembly 420 may include the light emitting module 240, the light guide plate 360, the optical sheets 320, the reflection sheet 330 and the receiving container 350.

The light guide plate 360 includes a light exiting surface 361 exiting light to the display panel 120, a light reflecting surface 362 facing the light exiting surface 361, and side surfaces 363 connecting the light exiting surface 361 with the light reflecting surface 362. A chamfered surface 365 is defined at a corner portion of the light guide plate 260, through which the side surfaces 363 of the light guide plate 360 are connected to each other.

The light emitting module 240 faces the chamfered surface 365 of the light guide plate 360, and includes light emitting package 242, and lead frame 244 on which the light emitting package 242 is mounted. A signal wiring (not shown) for providing the light emitting packages 242 with a driving voltage is on the lead frame 244.

Inner structures and functions of the light emitting package 244 are substantially the same as those of the light emitting package 260 in FIG. 4. Thus, the same reference numerals will be used to refer to same or like parts as those described in the previous exemplary embodiment.

The light emitting package 242 emits light to the chamfered surface 365, and the lead frame 244 is attached to the light emitting package 242 in a direction opposite to a direction in which the light is emitted.

The lead frame 244 includes a third lead 672, a fourth lead 674 and a molding part 676. The molding part 676 has a triangular column shape having a right angle in the plan view, and the right angle of the triangular column shape is disposed at a corner portion of the receiving container 350. The corner portion of the receiving container 350 is defined by two adjacent sidewalls. The molding part 676 has a pad and an electrical circuit, and thus the lead frame 244 may replace a conventional PCB. Thus, the light emitting module 240 may be received in the receiving container 350 having a shape suitable for the light emitting module 240, even though the light emitting module 240 is disposed to face the corner portion of the light guide plate 360.

In the illustrated exemplary embodiment, the light emitting module 240 is disposed to face the chamfered surface 365 defined at the corner portion of the light guide plate 360, but not limited thereto. Alternatively, the light emitting module 240 may be further disposed to face at least one of the side surfaces 363. In this case, a first light emitting chip 261 in the light emitting module 240 facing the chamfered surface 365 of the light guide plate 360, and a second light emitting chip 261 in the light emitting module 240 facing the side surface 363 may emit light having different radiation angles, so as to decrease a dark area of the display panel 120.

An exemplary embodiment of a method of manufacturing the light emitting module 240 in FIGS. 9 to 11 is described as follows.

The light emitting package 242 is formed. In one exemplary embodiment, for example, the first lead 262 on which the light emitting chip 261 is mounted and which is electrically connected to the first electrode of the light emitting chip 261, is formed. The second lead 263 electrically connected to the second electrode of the light emitting chip 261 is formed. The first wire 264 electrically connecting the light emitting chip 261 with the first lead 262, and the second wire 265 electrically connecting the light emitting chip 261 with the second lead 263 are formed. The case 266 which receives the light emitting chip 261 and includes the opening through which the light generated from the light emitting chip 261 exits, and through which the first lead 262 and the second lead 263 penetrate, is formed, and thus the light emitting package 242 is formed.

The lead frame 244 is formed. In one exemplary embodiment, for example, the third lead 672 and the fourth lead 674 are formed. The molding part 676 including the third lead 672 and the fourth lead 674 therein, and having the triangular column planar shape having the right angle corresponding to the corner portion of the receiving container 350, is formed. Thus, the lead frame 244 is formed.

The light emitting package 242 is mounted on the lead frame 244 so that the first lead 262 of the light emitting package 242 makes contact with the third lead 672 of the lead frame 244, and the second lead 263 of the light emitting package 242 makes contact with the fourth lead 674 of the lead frame 244.

According to the illustrated exemplary embodiment, the molding part 676 of the lead frame 244 has the triangular column shape having the right angle corresponding to the corner portion of the receiving container 350. Thus, the light emitting module 240 may be firmly received in the receiving container 350.

According to exemplary embodiments of the light emitting module, the method of manufacturing the light emitting module, and the display apparatus having the light emitting module, a lead frame dissipating heat more efficiently is between a light emitting package and a receiving container, and thus the heat generated from a light emitting chip of the light emitting package may be quickly dissipated to outside of the display apparatus.

In addition, the light emitting package is mounted on the lead frame having a width in a thickness direction of the display apparatus substantially same as a width of the light emitting package and supplying a driving voltage to the light emitting chip, and thus an overall thickness of a display apparatus may be decreased.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. A light emitting module comprising:
a light emitting package including:
a light emitting chip emitting light,
a first lead electrically connected to the light emitting chip, and
a second lead spaced apart from the first lead and electrically connected to the light emitting chip; and
a lead frame on which the light emitting package is mounted, and including:
a third lead electrically connected to the first lead,
a fourth lead electrically connected to the second lead; and
a molding part including the third lead and the fourth lead therein.

2. The light emitting module of claim 1, wherein the third lead and the fourth lead each include a circuit pattern in a quadrangle shape and in a line shape, in a plan view.

3. The light emitting module of claim 1, wherein the light is emitted from the light emitting chip in a direction opposite to a direction in which the lead frame is disposed.

4. The light emitting module of claim 1, further comprising:
a case including the light emitting chip therein and having an open top portion through which the light emitted from the light emitting chip exits,
wherein a width of the case in a first direction is substantially the same as a width of the lead frame in the first direction.

5. The light emitting module of claim 1, wherein
the molding part is a bar shape, and
a plurality of the light emitting chips are mounted on the molding part.

6. The light emitting module of claim 1, wherein
the light emitting package further includes a fifth lead on which the light emitting chip is mounted, and
the lead frame further includes a heat dissipating portion connected to the fifth lead and through which heat generated from the light emitting chip is dissipated to outside.

7. A method of manufacturing a light emitting module, the method comprising:
forming light emitting packages, each of the light emitting packages including a light emitting chip emitting light, a first lead electrically connected to the light emitting chip and a second lead electrically connected to the light emitting chip;
forming a third lead electrically which is connected to the first lead, and a fourth lead which is electrically connected to the second lead;
covering the third lead and the fourth lead with a molding resin;
forming a lead frame by hardening the molding resin;
mounting the light emitting packages on the lead frame in a matrix pattern; and
cutting the lead frame on which the light emitting packages are mounted, in a longitudinal direction of the light emitting packages.

8. The method of claim 7, wherein the mounting the light emitting packages in the matrix pattern includes using a surface mount technology.

9. The method of claim 7, wherein the forming the third lead and the fourth lead includes forming a circuit pattern on the third and fourth leads using a punching method or a photo mask method.

10. A display apparatus comprising:
a light guide plate including a light incident surface into which light is incident, and a light exiting surface connected to the light incident surface and through which the light exits;
a light emitting module including a light emitting package, and a lead frame on which the light emitting package is mounted,
the light emitting package including:
a light emitting chip emitting the light to the incident surface,
a first lead electrically connected to the light emitting chip, and
a second lead spaced apart from the first lead and electrically connected to
the light emitting chip,
the lead frame including:
a third lead electrically connected to the first lead,
a fourth lead electrically connected to the second lead, and
a molding part including the third lead and the fourth lead therein; and
a display panel displaying an image using the light exiting from the light exiting surface of the light guide plate.

11. The display apparatus of claim 10, further comprising a receiving container including a bottom plate, and a sidewall extending from the bottom plate, the light guide plate and the light emitting module in the receiving container,
wherein
the sidewall of the receiving container faces the incident surface of the light guide plate, and
the lead frame contacts the sidewall.

12. The display apparatus of claim 10, wherein
the light emitting package further includes a fifth lead on which the light emitting chip is mounted, and
the lead frame further includes a heat dissipating portion connected to the fifth lead and through which generated from the light emitting chip is dissipated to outside of the light emitting module.

13. The display apparatus of claim 12, wherein the heat dissipating portion of the lead frame is in contact with the sidewall of the receiving container.

14. The display apparatus of claim 10, further comprising:
a reflection sheet between the receiving container and the light emitting module, and between the receiving container and the light guide plate.

15. The display apparatus of claim 10, wherein the light guide plate further includes:
a side surface extending from the light exiting surface; and
a combining groove extending from both the light exiting surface and the side surface.

16. The display apparatus of claim 15, wherein the molding part of the lead frame comprises:
a main portion facing the light emitting chip, and including the third lead and the fourth lead therein;
an extending portion extending from the main portion toward the light guide plate; and
a protruding portion protruded from the extending portion and combined with the combining groove of the light guide plate.

17. The display apparatus of claim 15, wherein the combining groove is adjacent to the incident surface.

18. The display apparatus of claim 17, further comprising optical sheets between the light exiting surface of the light guide plate and the display panel,
wherein the combining groove extends from the light exiting surface of the light guide plate except for an area overlapping the optical sheets.

19. The display apparatus of claim 10, wherein
the light guide plate further includes a light reflecting surface opposing the light exiting surface, and side surfaces connecting the light exiting surface with the light reflecting surface, and
the light incident surface of the light guide plate is a chamfered surface through which adjacent side surfaces are connected to each other.

20. The display apparatus of claim 19, wherein
the molding part of the lead frame is a triangular column planar shape having a right angle, and
the right angle of the triangular column is disposed at a corner portion of the receiving container.
